(19) United States
(12) Patent Application Publication
(10) Pub. No.: US 2021/0364555 A1
(43) Pub. Date: Nov. 25, 2021

(54) CURRENT DETECTION CIRCUIT APPLIED TO SIC FIELD EFFECT TRANSISTOR

(71) Applicant: XI'AN JIAOTONG UNIVERSITY, Xi'an (CN)

(72) Inventors: Laili WANG, Xi'an (CN); Chengzi YANG, Xi'an (CN); Huaqing LI, Xi'an (CN); Xingshuo LIU, Xi'an (CN); Longyang YU, Xi'an (CN); Yunqing PEI, Xi'an (CN); Yongmei GAN, Xi'an (CN); Xu YANG, Xi'an (CN)

(21) Appl. No.: 17/220,924

(22) Filed: Apr. 1, 2021

(30) Foreign Application Priority Data
May 21, 2020 (CN) 202010438104.6

(51) Int. Cl. G01R 19/25

(52) U.S. Cl. CPC G01R 19/25

(57) ABSTRACT

The present invention provides a current detection circuit applied to a SiC field effect transistor. The current detection circuit includes a current detection loop and an acquisition loop on the current detection loop. The current detection loop includes a voltage source, a capacitor, a first SiC field effect transistor, a second SiC field effect transistor, and a sampling resistor. The first SiC field effect transistor is connected to a power signal. The second SiC field effect transistor is connected to a pulse signal. The acquisition loop includes a compensating resistor and a compensating inductor. The compensating resistor and the compensating inductor are connected in series and then connected in parallel at two ends of the sampling resistor to counteract the influence of total parasitic inductance in the current detection loop.

### CROSS-REFERENCE TO RELATED APPLICATIONS

This application claims priority to Chinese Application No. 202010438104.6, filed on May 21, 2020, entitled “Current detecting circuit and detecting method”. These contents are hereby incorporated by reference.

### TECHNICAL FIELD

The present invention relates to the field of SiC field effect transistors, and particularly to a current detection circuit applied to a SiC field effect transistor.

### BACKGROUND

A power semiconductor device is a key component of power electronic equipment. In 1957, the General Electric developed the first thyristor, which marked the birth of a power electronic technology. Since the 1990s, with the continuous in-depth research and understanding of SiC materials and the gradual improvement of SiC epitaxy technologies, power electronic devices based on SiC materials have been commercialized and are gradually used in some application occasions where original silicon devices are not suitable, such as high-temperature, high-pressure, high-efficiency, small-volume, and small-space application occasions. A subsequent technical problem is how to detect the switching performance of a SiC MOSFET. In general, a method of detecting and observing a current by using a current sampling resistor (CSR) is easy to design and reliable. However, when the CSR is configured to detect a transient current caused by switching of a power device, especially a fast-switching SiC MOSFET with high di/dt, even in a non-switching state, the presence of a small parasitic inductance may also have a great impact on detection results. In order to reduce the influence of parasitic inductance on high-power and high-frequency current detection, a better detection method is needed.

At present, better transient current detection methods are as follows:

1) A coaxial shunt resistor is used for detection. The coaxial shunt resistor uses its coaxial structure to generate no magnetic field internally. When the current flows through inner and outer resistor tubes into the coaxial shunt resistor, there may be no obvious magnetic flux in an inner cylinder.

2) A Kelvin four-wire resistor is used for detection. A Kelvin four-wire connection can be used to reduce the influence of wire resistance and inductance of high-precision resistors with very low ohmic values in current detection.

The coaxial shunt resistor can well avoid the generation of parasitic inductance. Since the inner cylinder thereof does not generate a significant magnetic flux, an output line can extend in the inner cylinder for current measurement without any induced voltage. Due to a coaxial structure and a manufacturing process, the coaxial shunt resistor is too large in volume and high in manufacturing cost, so the coaxial shunt resistor is not suitable for wide application.

A Kelvin four-wire current sampling resistor allows a current to be measured through two opposite terminals and an induced voltage to be measured between the other two terminals, so as to perform more accurate current measurement. Although the Kelvin four-wire connection can avoid the influence of external parasitic inductance on current detection, the influence of internal parasitic inductance cannot be ignored, so it is not very suitable for high-power and high-frequency current detection. Therefore, there is a need to develop a detection dialup to avoid the influence of parasitic inductance on the detection performance of the current sampling resistor.

### SUMMARY OF THE INVENTION

An objective of the present invention is to provide a current detection circuit applied to a SiC field effect transistor, so as to overcome the disadvantages of the prior art. The detection circuit can effectively avoid the influence of parasitic inductance on the detection performance of the current sampling resistor, and is less costly and smaller.

The current detection circuit includes a current detection loop and an acquisition loop on the current detection loop;

the current detection loop includes a voltage source, a capacitor, a first SiC field effect transistor, a second SiC field effect transistor, and a sampling resistor; a positive electrode of the voltage source is electrically connected to a D pole of the first SiC field effect transistor, an S pole of the first SiC field effect transistor is electrically connected to a D pole of the second SiC field effect transistor, the D pole of the second SiC field effect transistor is electrically connected to a negative electrode of the voltage source through the sampling resistor, and the capacitor is connected in parallel to two ends of the voltage source, wherein a power signal is connected between a G pole and the S pole of the first SiC field effect transistor, and a pulse signal is connected between a G pole and an S pole of the second SiC field effect transistor;

the acquisition loop includes a compensating resistor and a compensating inductor; a sum of currents of the compensating resistor and the sampling resistor is acquired through a current acquisition device, and a voltage at two ends of the compensating resistor is acquired through the current acquisition device, wherein the compensating resistor and the compensating inductor are connected in series and then connected in parallel at two ends of the sampling resistor to counteract the influence of total parasitic inductance in the current detection loop.

Preferably, the total parasitic inductance comprises: internal parasitic inductance and external parasitic inductance of the sampling resistor, wherein a value of the total parasitic inductance is a sum of the internal parasitic inductance and the external parasitic inductance.

Preferably, parameter design of the current detection circuit meets a constraint condition of L_{C}>>L_{S}, R_{C}>>R_{S} and

$$\frac{{L}_{C}}{{R}_{C}} = \frac{{L}_{S}}{{R}_{S}} ,$$

so that the compensating inductor in the acquisition loop completely counteracts the influence of the total parasitic inductance produced during measurement of a quick change current, wherein L_{S} denotes an inductance value of the total parasitic inductance, R_{C} denotes a resistance value of the compensating resistor, R_{S} denotes a resistance value of the sampling resistor, and L_{C} denotes an inductance value of the compensating inductor.

Preferably, a transfer function model of a current id on the acquisition loop to the voltage Vsc at the two ends of the compensating resistor is:

$${G}_{sc 0} ( s ) = \frac{{sL}_{S} {R}_{C} + {R}_{S} {R}_{C}}{s ( {L}_{S} + {L}_{C} ) + ( {R}_{S} + {R}_{C} )} ;$$

when L_{C}>>L_{S}, R_{C}>>R_{S} and

$$\frac{{L}_{C}}{{R}_{C}} = \frac{{L}_{S}}{{R}_{S}} ,$$

Gsc0(s) is simplified into:

Preferably, the inductance value L_{C} of the compensating inductor is in a range of 470 nH<L_{C}≤4.7 μH.

Preferably, a self-resonant frequency of the compensating inductor is higher than 50 MHz.

Preferably, a transfer function model of the current id on the acquisition loop to the voltage Vsc at the two ends of the compensating resistor is:

$${G}_{sc 1} ( s ) = \frac{\text{?}}{{i}_{d}} - \frac{{Z}_{S} \cdot {R}_{C}}{{Z}_{S} + {Z}_{C}} ;$$

$$\text{?} \text{indicates text missing or illegible when filed}$$

wherein, Z_{S}=sL_{S}+R_{S},

$${Z}_{C} = \frac{{sL}_{C}}{{s}^{2} {C}_{C} {L}_{C} + 1} + {R}_{C} ;$$

therefore:

$${G}_{sc 1} ( s ) = \frac{( {sL}_{S} + {R}_{S} ) ( {s}^{2} {C}_{C} {L}_{C} + 1 ) {R}_{C}}{( {sL}_{S} + {R}_{S} ) ( {s}^{2} {C}_{C} {L}_{C} + 1 ) {s}^{2} {C}_{C} {L}_{C} {R}_{C} + {sL}_{C} + {R}_{C}} ;$$

When L_{C}>>L_{S}, R_{C}>>R_{S}; G_{sc1}(s) is simplified into:

$${G}_{sc 1} ( s ) = {R}_{S} \frac{( s \frac{{L}_{S}}{{R}_{S}} + 1 ) ( {s}^{3} {C}_{C} {L}_{C} + 1 )}{( s \frac{{L}_{C}}{{R}_{C}} + 1 ) + {s}^{2} {C}_{C} {L}_{C}} .$$

Preferably, a transfer function model of the current id on the acquisition loop to the voltage Vsc at the two ends of the compensating resistor is:

$${G}_{sc 2} ( s ) = \frac{\text{?}}{{i}_{d}} = \frac{{Z}_{S} ( {R}_{C} + {sL}_{RC} )}{{Z}_{S} + {Z}_{C}} ;$$

$$\text{?} \text{indicates text missing or illegible when filed}$$

wherein Z_{S}=sL_{S}+R_{S} and Z_{C}=s(L_{C}+L_{RC})+R_{C}; therefore:

$${G}_{sc 2} ( s ) = \frac{{s}^{3} {L}_{RC} {L}_{S} + s ( {R}_{C} {L}_{S} + {L}_{RC} {R}_{S} ) + {R}_{C} {R}_{S}}{s ( {L}_{S} + {L}_{C} + {L}_{RC} ) + {R}_{C} + {R}_{S}} ;$$

when L_{C}>>L_{S} and R_{C}>>R_{S}, G_{sc2}(s) is simplified into:

$${G}_{sc 2} ( s ) = {R}_{S} \frac{( s \frac{{L}_{S}}{{R}_{S}} + 1 ) + {s}^{3} \frac{{L}_{RC} {L}_{S}}{{R}_{C} {R}_{S}} + s \frac{{L}_{RC}}{{R}_{C}}}{( s \frac{{L}_{C} + {L}_{RC}}{{R}_{C}} + 1 )} .$$

Preferably, a transfer function model of the current id on the acquisition loop to the voltage Vsc at the two ends of the compensating resistor is:

$${G}_{sc 3} ( s ) = \frac{{v}_{sc}}{{i}_{d}} = \frac{{R}_{C}}{{sR}_{C} {C}_{L} + 1} \cdot \frac{{Z}_{S}}{{Z}_{S} + {Z}_{C}} ;$$

wherein Z_{S}=sL_{S}+R_{S} and

$${Z}_{C} = {sL}_{C} + \frac{{R}_{C}}{( {sR}_{C} {C}_{L} + 1 )} ,$$

therefore:

$${G}_{sc 3} ( s ) = \frac{( {sL}_{S} + {R}_{S} ) {R}_{C}}{( s ( {L}_{S} + {L}_{C} ) + {R}_{S} ) ( {sR}_{C} {C}_{L} + 1 ) + {R}_{C}} ;$$

when L_{C}>>L_{S} and R_{C}>>R_{S}, Gsc2(s) is simplified into:

$${G}_{sc 3} ( s ) = {R}_{S} \frac{( s \frac{{L}_{S}}{{R}_{S}} + 1 )}{( s \frac{{L}_{C}}{{R}_{C}} + \frac{{R}_{S}}{{R}_{C}} ) ( {sR}_{C} {C}_{L} + 1 ) + 1} .$$

Preferably, the total parasitic inductance is obtained by double pulse measurement, and a generation model thereof is:

$${L}_{S} = \frac{\text{?}}{4 {π}^{3} \text{?}} \frac{Δ {V}_{S}}{Δ {V}_{DS}} ;$$

$$\text{?} \text{indicates text missing or illegible when filed}$$

wherein T_{ring} denotes a ringing period of a drain-source voltage of the second SiC field effect transistor, and C_{oss@Vin} denotes an output capacitance of the second SiC field effect transistor when an input voltage is Vin, wherein ΔV_{DS} and ΔV_{S} denote peak-to-peak values of V_{DS} and V_{S} respectively.

Based on the current detection circuit applied to a SiC field effect transistor according to the present invention, during a specific detection operation, the compensating resistor and the compensating inductor form a compensating branch. A value of the compensating inductor is much larger than that of the total parasitic inductance and a value of the compensating resistor is much larger than that of the sampling resistor so that the parasitic inductance can be ignored, and

$$\frac{{L}_{C}}{{R}_{C}} = \frac{{L}_{S}}{{R}_{S}} .$$

A branch consisting of the current sampling resistor and the total parasitic inductance is connected in parallel with the compensating branch, through which the total parasitic inductance is compensated. The circuit is smaller, which can effectively avoid the influence of parasitic inductance on the detection performance of the current sampling resistor.

### BRIEF DESCRIPTION OF DRAWINGS

FIG. 1 is a schematic diagram of a double-pulse test according to an embodiment of the present invention;

FIG. 2 is a schematic diagram of parasitic inductance according to an embodiment of the present invention;

FIG. 3 is a schematic diagram of the influence of parasitic inductance according to an embodiment of the present invention;

FIG. 4 is a schematic diagram of a compensating branch according to an embodiment of the present invention;

FIG. 5 is a diagram of the influence of parasitic parameters on the performance of a current sensing circuit according to an embodiment of the present invention;

FIG. 6 shows the influence of a CC on a current sensing circuit in a range of 0.5 to 2.5 pF according to an embodiment of the present invention;

FIG. 7 shows the influence of an LRC on characteristics of a current sensing circuit in a range of 1 nh to 5 nh according to an embodiment of the present invention;

FIG. 8 shows the influence of a CL on characteristics of a current sensing circuit in a range of 1 to 9 pF according to an embodiment of the present invention; and

FIG. 9 is a diagram of experimental results for LS calculation according to an embodiment of the present invention.

### DETAILED DESCRIPTION OF PREFERRED EMBODIMENTS

To make the objectives, technical solutions, and advantages of implementations of the present invention clearer, the technical solutions in the implementations of the present invention are clearly and completely described below with reference to the drawings in the implementations of the present invention. The following detailed description of the implementations of the present invention provided in the drawings is not intended to limit the scope of the present invention for which protection is sought, but merely to indicate selected implementations of the present invention.

Specific embodiments of the present invention are described in detail below with reference to the drawings.

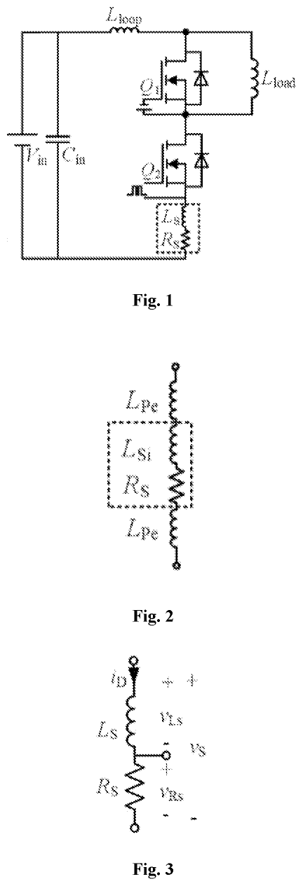

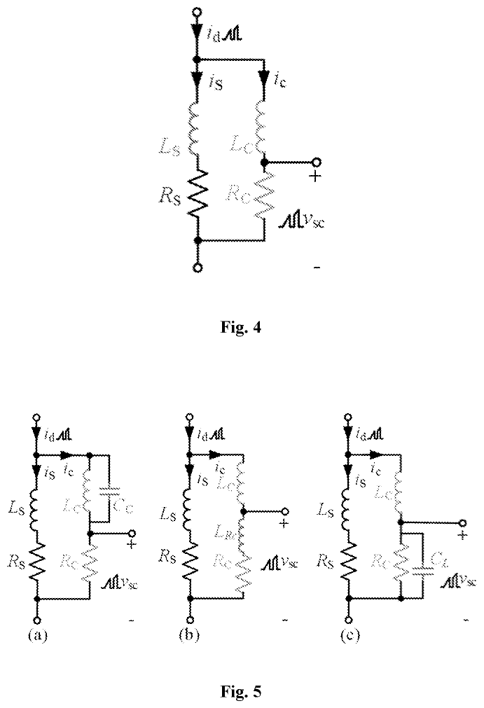

Referring to FIG. 1 to FIG. 4, an embodiment of the present invention provides a current detection circuit applied to a SiC field effect transistor, the current detection circuit including:

a current detection loop and an acquisition loop on the current detection loop.

The current detection loop includes a voltage source Vin, a capacitor Cin, a first SiC field effect transistor Q1, a second SiC field effect transistor Q2, and a sampling resistor Rs; a positive electrode of the voltage source Vin is electrically connected to a D pole of the first SiC field effect transistor Q1, an S pole of the first SiC field effect transistor Q1 is electrically connected to a D pole of the second SiC field effect transistor Q2, the D pole of the second SiC field effect transistor Q2 is electrically connected to a negative electrode of the voltage source Vin through the sampling resistor Rs, and the capacitor Cin is connected in parallel to two ends of the voltage source Vin, wherein a power signal is connected between a G pole and the S pole of the first SiC field effect transistor Q1, and a pulse signal is connected between a G pole and an S pole of the second SiC field effect transistor Q2.

The acquisition loop includes a compensating resistor and a compensating inductor; a sum of currents of the compensating resistor and the sampling resistor is acquired through a current acquisition device, and a voltage at two ends of the compensating resistor is acquired through the current acquisition device, wherein the compensating resistor Rc and the compensating inductor Lc are connected in series and then connected in parallel at two ends of the sampling resistor Rs to counteract the influence of total parasitic inductance Lsi in the current detection loop.

In this embodiment, the total parasitic inductance Lsi includes: internal parasitic inductance and external parasitic inductance of the sampling resistor Rs, wherein a value of the total parasitic inductance Lsi is a sum of the internal parasitic inductance and the external parasitic inductance.

It needs to be noted that L_{Pe} denotes the external parasitic inductance, mainly caused by PCB layout, which can be minimized by advanced layout, and L_{Si} denotes the internal parasitic inductance of the current sampling resistor RsCSR. L_{Si} is determined by materials and a manufacturing process. L_{Si} varies greatly among different current sampling resistors RsCSR. A sum of L_{Pe} and L_{Si} is equal to the total parasitic inductance Lsi of the current sampling resistor RsCSR.

In this embodiment, a transfer function model of a current id on the acquisition loop to the voltage Vsc at the two ends of the compensating resistor Rc is:

$$\text{?} ( s ) = \frac{\text{?} {L}_{S} {R}_{C} + {R}_{S} {R}_{C}}{\text{?} ( {L}_{S} + {L}_{C} ) + ( {R}_{S} + {R}_{C} ) ;}$$

$$\text{?} \text{indicates text missing or illegible when filed}$$

wherein L_{S} denotes an inductance value of the total parasitic inductance Lsi, R_{C} denotes a resistance value of the compensating resistor Rc, R_{S} denotes a resistance value of the sampling resistor Rs, and L_{C} denotes an inductance value of the compensating inductor Lc;

when L_{C}>>L_{S}, R_{C}>>R_{S} and

$$\frac{{L}_{C}}{{R}_{C}} = \frac{{L}_{S}}{{R}_{S}} ,$$

Gsc0(s) is simplified into:

G_{sc0}(s)=R_{S}.

In this embodiment, the inductance value of the compensating inductor Lc is in a range of 470 nH<L_{C}≤4.7 μH.

In this embodiment, a self-resonant frequency of the compensating inductor Lc may be higher than 50 MHz.

Referring to FIG. 5 to FIG. 8, in this embodiment, as shown in FIG. 5(a), in consideration of a current sensing circuit of parasitic capacitance Cin of LC, a transfer function model of the current id on the acquisition loop to the voltage Vsc at the two ends of the compensating resistor Rc is:

$${G}_{sc 1} ( s ) = \frac{\text{?}}{{i}_{d}} = \frac{{Z}_{S} \cdot {R}_{C}}{{Z}_{S} + {Z}_{C}} ;$$

$$\text{?} \text{indicates text missing or illegible when filed}$$

wherein Z_{S}=sL_{S}+R_{S}, and

$${Z}_{C} = \frac{{sL}_{C}}{{s}^{3} {C}_{C} {L}_{C} + 1} + {R}_{C} ;$$

therefore:

$${G}_{sc 1} ( s ) = \frac{( \text{?} {L}_{S} + {R}_{S} ) ( {s}^{2} {C}_{C} {L}_{C} + 1 ) {R}_{C}}{( \text{?} {L}_{S} + {R}_{S} ) ( \text{?} {C}_{C} {L}_{C} + 1 ) \text{?} {C}_{C} {L}_{C} {R}_{C} + ? {L}_{C} + {R}_{C}} ;$$

$$\text{?} \text{indicates text missing or illegible when filed}$$

when L_{C}>>L_{S}, and R_{C}>>R_{S}; G_{sc1}(s) is simplified into:

$${G}_{sc 1} ( s ) = {R}_{S} \frac{( s \frac{{L}_{S}}{{R}_{S}} + 1 ) ( {s}^{2} {C}_{C} {L}_{C} + 1 )}{( s \frac{{L}_{C}}{{R}_{C}} + 1 ) + {s}^{2} {C}_{C} {L}_{C}} .$$

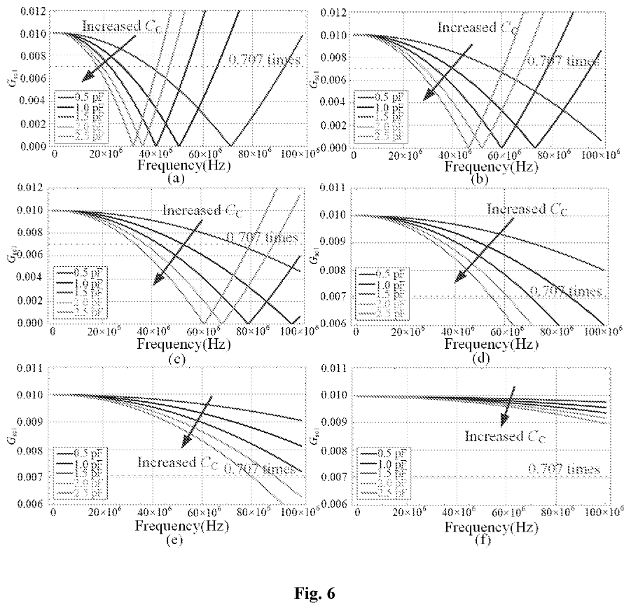

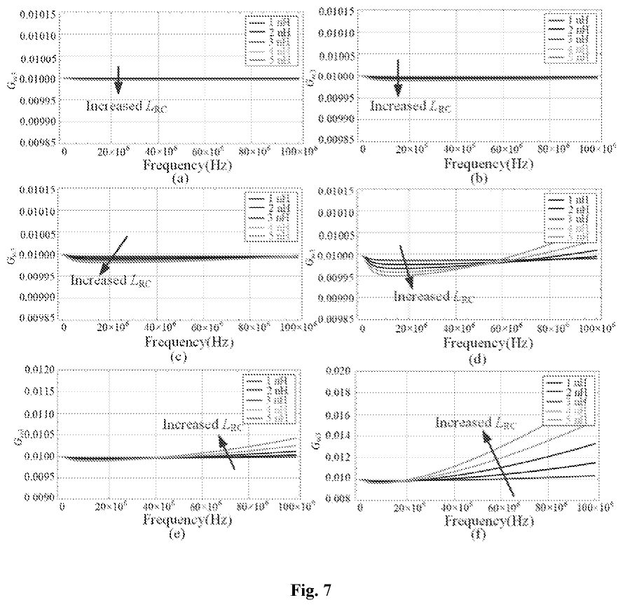

It needs to be noted that, in consideration of the influence of CC, frequency-domain characteristics of the current sensing circuit proposed can be calculated, as shown in FIG. 6. When values of LC are 10 μH, 4.7 μH, 2.7 μH, 1 μH, 470 nh, and 100 nh respectively, the influence of CC in a range of 0.5 pf to 2.5 pf on the current sensing circuit is as shown in FIG. 6. Under a low frequency, the amplitude of Gsc1 is 0.01, which is the value of RS. However, with the increase of the frequency, the amplitude of Gsc1 attenuates. A greater CC indicates faster signal attenuation. For FIG. 6(a), FIG. 6(b), and FIG. 6(c), the amplitude of Gsc1 has an angular frequency within 100 MHz. With the decrease of the value of CC, a corner frequency is increased. For FIG. 6(d), FIG. 6(e), and FIG. 6(f), the corner frequency may be higher than 100 MHz. With the decrease of the value of LC, an amplitude attenuation rate of Gsc1 is decreased, and the current sensing circuit may obtain a higher bandwidth. Based on the above, the values of LC and CC should be as small as possible to obtain a higher bandwidth when only the influence of CC is taken into account.

In this embodiment, as shown in FIG. 5(b), in consideration of a current sensing circuit of parasitic capacitance of LRC, a transfer function model of the current id on the acquisition loop to the voltage Vsc at the two ends of the compensating resistor Rc is:

$${G}_{sc 2} ( s ) = \frac{\text{?}}{{i}_{d}} = \frac{{Z}_{S} ( {R}_{C} + {sL}_{RC} )}{{Z}_{S} + {Z}_{C}} ;$$

$$\text{?} \text{indicates text missing or illegible when filed}$$

wherein Z_{S}=sL_{S}+R_{S} and Z_{C}=s(L_{C}+L_{RC})+R_{C}; therefore:

$${G}_{sc 2} ( s ) = \frac{{s}^{3} {L}_{RC} {L}_{S} + s ( {R}_{C} {L}_{S} + {L}_{RC} {R}_{S} ) + {R}_{C} {R}_{S}}{s ( {L}_{S} + {L}_{C} + {L}_{RC} ) + {R}_{C} + {R}_{S}} ;$$

when L_{C}>>L_{S} and R_{C}>>R_{S}, Gsc2(s) is simplified into:

$${G}_{sc 2} ( s ) = {R}_{S} \frac{( s \frac{{L}_{S}}{{R}_{S}} + 1 ) {s}^{2} \frac{{L}_{RC} {L}_{S}}{{R}_{C} {R}_{S}} + s \frac{{L}_{RC}}{{R}_{C}}}{( s \frac{{L}_{C} + {L}_{RC}}{{R}_{C}} + 1 )} .$$

It needs to be noted that, in consideration of the influence of LRC, frequency-domain characteristics of the current sensing circuit proposed can be calculated, as shown in FIG. 7. When values of LC are 10 μH, 4.7 μH, 2.7 μH, 1 μH, 470 nh, and 100 nh respectively, the influence on the parasitic inductance LRC in a range of 1 nh to 5 nh is as shown in FIG. 7. When the value of LC is greater than 2.7 μH, a change of LRC almost has no influence on Gsc2. When the value of LC is in a range of 1 μH to 470 nh, a change of the value of LRC has acceptable influence on Gsc2, as shown in FIG. 7(d) and FIG. 7(e). In this case, an error in the worst case is less than 5%, so the influence is negligible. As shown in FIG. 7(f), when the value of LC is 100 nH, with the increase of LRC, the influence on Gsc2 becomes significant. In conclusion, when the value of LC is greater than 470 nh, the influence of LRC on Gsc2 can be ignored.

In this embodiment, as shown in FIG. 5(c), in consideration of a current sensing circuit of CL, a transfer function model of the current id on the acquisition loop to the voltage Vsc at the two ends of the compensating resistor Rc is:

$${G}_{sc 3} ( s ) = \frac{\text{?}}{{i}_{d}} = \frac{{R}_{C}}{{sR}_{C} {C}_{L} + 1} \cdot \frac{{Z}_{S}}{{Z}_{S} + {Z}_{C}} ;$$

$$\text{?} \text{indicates text missing or illegible when filed}$$

wherein Z_{S}=sL_{S}+R_{S} and

$${Z}_{C} = {sL}_{C} + \frac{{R}_{C}}{( {sR}_{C} {C}_{L} + 1 )} ,$$

therefore:

$${G}_{sc 3} ( s ) = \frac{( {sL}_{S} + {R}_{S} ) {R}_{C}}{( s ( {L}_{S} + {L}_{C} ) + {R}_{S} ) ( {sR}_{C} {C}_{L} + 1 ) + {R}_{C}} ;$$

when L_{C}>>L_{S} and R_{C}>>R_{S}, Gsc2(s) is simplified into:

$${G}_{sc 3} ( s ) = {R}_{S} \frac{( s \frac{{L}_{S}}{{R}_{S}} + 1 )}{( s \frac{{L}_{C}}{{R}_{C}} + \frac{{R}_{S}}{{R}_{C}} ) ( {sR}_{C} {C}_{L} + 1 ) + 1} .$$

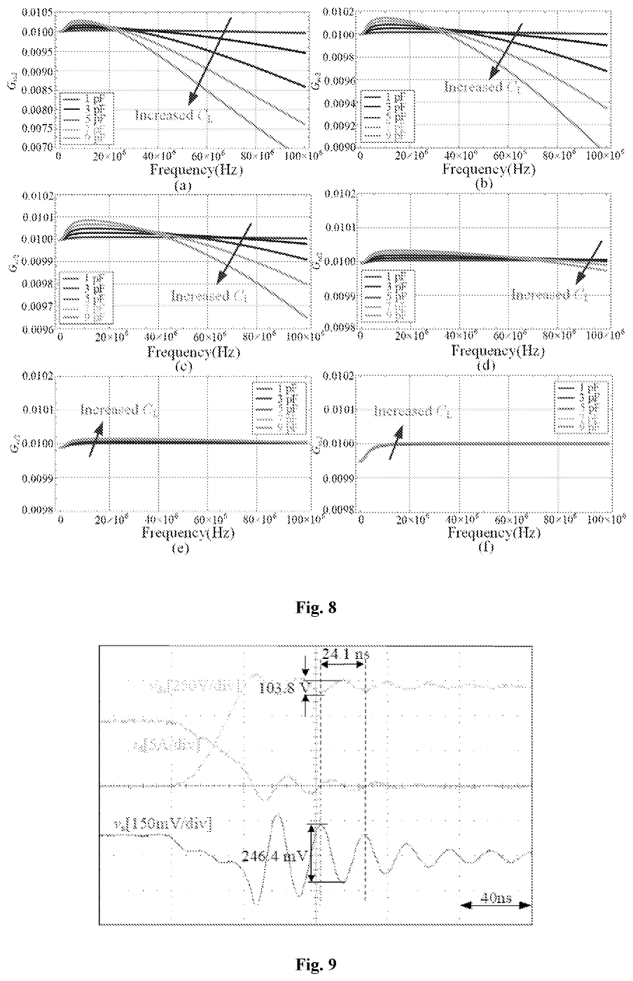

It needs to be noted that, in consideration of the influence of CL, frequency-domain characteristics of the current sensing circuit proposed can be calculated, as shown in FIG. 8. When values of LC are 10 μH, 4.7 μH, 2.7 μH, 1 μH, 470 nh, and 100 nh respectively, the influence on CL in a range of 1 pf to 9 pf is as shown in FIG. 8. When the value of LC is greater, the value of DC of Gsc3 is 0.01, which is the value of RS. However, when the value of LC is less than 1 μH, the DC amplitude of Gsc3 is slightly less than 0.01, which is mainly because the value of RC is decreased with the decrease of the value of LC, satisfying LC/RC=LS/RS. Under a DC condition, a too small RC may affect the amplitude of Gsc3. On the other hand, it can be seen from FIG. 8 that when the value of CL is increased but is within 5 pF, the value of LC and the frequency have acceptable influence on the magnitude of Gsc3. When the value of LC is less than 2.7 μH, the further increase of CL almost has no influence on Gsc3. However, when values of LC are 10 μH and 4.7 μH, the further increase of CL may obviously reduce the magnitude of Gsc3, as shown in FIG. 8(a) and FIG. 6(b). That is, when the value of Lc is greater than 2.7 μH, CL should be controlled within 5 pf, so as to obtain a higher bandwidth. When the value of Lc is less than 2.7 μH, the influence of CL on Gsc3 is weak and can be ignored.

In this embodiment, the total parasitic inductance Lsi is obtained by double pulse measurement, and a generation model thereof is:

$${L}_{S} = \frac{{T}_{ring}^{3}}{4 {π}^{3} {C}_{oss @ Vin}} \frac{Δ {V}_{S}}{Δ {V}_{DS}} .$$

As shown in FIG. 9, the present invention also provides a simple and accurate L_{S} test method. A double-pulse test is adopted.

T_{ring} denotes a ringing period of a drain-source voltage of the second SiC field effect transistor Q2, and C_{oss@Vin} denotes an output capacitance of the second SiC field effect transistor Q2 when an input voltage is Vin, wherein ΔV_{DS} and ΔV_{S} denote peak-to-peak values of V_{DS} and V_{S} respectively.

Based on the current detection circuit applied to a SiC field effect transistor, during a specific detection operation, the compensating resistor Rc and the compensating inductor Lc form a compensating branch. A branch consisting of the current sampling resistor Rs and the total parasitic inductance Lsi is connected in parallel with the compensating branch, through which the total parasitic inductance Lsi is compensated. The circuit is smaller, which can effectively avoid the influence of parasitic inductance on the detection performance of the current sampling resistor Rs.

In the present invention, the terms “first,” “second,” and “third” are merely for the purpose of description, but cannot be understood as indicating or implying relative importance. The term “multiple” means two or more unless otherwise explicitly defined. The terms “mount,” “connect with,” “connect,” “fix,” and the like shall be understood in a broad sense. For example, “connect” may mean being fixedly connected, detachably connected, or integrally connected; and “connect with” may mean being directly connected or indirectly connected through an intermediary. For those of ordinary skill in the art, specific meanings of the above terms in the present invention can be understood according to specific situations.

The above are merely preferred implementations of the present invention. The protection scope of the present invention is not merely limited to the above embodiments. Any technical solution under the idea of the present invention falls within the protection scope of the present invention.

1. A current detection circuit applied to a SiC field effect transistor, the current detection circuit comprising:
a current detection loop and an acquisition loop on the current detection loop;
wherein the current detection loop comprises a voltage source, a capacitor, a first SiC field effect transistor, a second SiC field effect transistor, and a sampling resistor; a positive electrode of the voltage source is electrically connected to a D pole of the first SiC field effect transistor, an S pole of the first SiC field effect transistor is electrically connected to a D pole of the second SiC field effect transistor, the D pole of the second SiC field effect transistor is electrically connected to a negative electrode of the voltage source through the sampling resistor, and the capacitor is connected in parallel to two ends of the voltage source, wherein a power signal is connected between a G pole and the S pole of the first SiC field effect transistor, and a pulse signal is connected between a G pole and an S pole of the second SiC field effect transistor;
the acquisition loop comprises a compensating resistor and a compensating inductor; a sum of currents of the compensating resistor and the sampling resistor is acquired through a current acquisition device, and a voltage at two ends of the compensating resistor is acquired through the current acquisition device, wherein the compensating resistor and the compensating inductor are connected in series and then connected in parallel at two ends of the sampling resistor to counteract the influence of total parasitic inductance in the current detection loop;
the total parasitic inductance comprises: internal parasitic inductance and external parasitic inductance of the sampling resistor, wherein a value of the total parasitic inductance is a sum of the internal parasitic inductance and the external parasitic inductance; and
parameter design of the current detection circuit meets a constraint condition of L_{C}>>L_{S}, R_{C}>>R_{S} and
$$\frac{{L}_{C}}{{R}_{C}} = \frac{{L}_{S}}{{R}_{S}} ,$$
so that the compensating inductor in the acquisition loop completely counteracts the influence of the total parasitic inductance produced during measurement of a quick change current, wherein L_{S} denotes an inductance value of the total parasitic inductance, R_{C} denotes a resistance value of the compensating resistor, R_{S} denotes a resistance value of the sampling resistor, and L_{C} denotes an inductance value of the compensating inductor.

2. The current detection circuit applied to a SiC field effect transistor according to claim 1, wherein a transfer function model of a current id on the acquisition loop to the voltage Vsc at the two ends of the compensating resistor is:
$${G}_{sc 0} ( s ) = \frac{{sL}_{S} {R}_{C} + {R}_{S} {R}_{C}}{s ( {L}_{S} + {L}_{C} ) + ( {R}_{S} + {R}_{C} )} ;$$
when L_{C}>>L_{S}, R_{C}>R_{S} and
$$\frac{{L}_{C}}{{R}_{C}} = \frac{{L}_{S}}{{R}_{S}} ,$$
Gsc0(s) is simplified into:
G_{sc0}(s)=R_{S}.

3. The current detection circuit applied to a SiC field effect transistor according to claim 1, wherein the inductance value L_{C} of the compensating inductor is in a range of 470 nH<L_{C}≤4.7 μH.

4. The current detection circuit applied to a SiC field effect transistor according to claim 1, wherein a self-resonant frequency of the compensating inductor is higher than 50 MHz.

5. The current detection circuit applied to a SiC field effect transistor according to claim 1, wherein a transfer function model of the current id on the acquisition loop to the voltage Vsc at the two ends of the compensating resistor is:
$${G}_{sc 1} = \frac{{v}_{sc}}{{t}_{d}} = \frac{{Z}_{S} \cdot {R}_{C}}{{Z}_{S} + {Z}_{C}} ;$$
wherein Z_{S}=sL_{S}+R_{S}, and
$${Z}_{C} = \frac{{sL}_{C}}{{s}^{3} {C}_{C} {L}_{C} + 1} + {R}_{C} ;$$
therefore:
$${G}_{sc 1} ( s ) = \frac{( {sL}_{S} + {R}_{S} ) ( {s}^{2} {C}_{C} {L}_{C} + 1 ) {R}_{C}}{( {sL}_{S} + {R}_{S} ) ( {s}^{2} {C}_{C} {L}_{C} + 1 ) + {s}^{3} {C}_{C} {L}_{C} {R}_{C} + {sL}_{C} + {R}_{C}} ;$$
when L_{C}>>L_{S}, and R_{C}>>R_{S}; G_{sc1}(s) is simplified into:
$${G}_{sc 1} ( s ) = {R}_{S} \frac{( s \frac{{L}_{S}}{{R}_{S}} + 1 ) ( {s}^{2} {C}_{C} {L}_{C} + 1 )}{( s \frac{{L}_{C}}{{R}_{C}} + 1 ) + {s}^{3} {C}_{C} {L}_{C}} .$$

6. The current detection circuit applied to a SiC field effect transistor according to claim 1, wherein a transfer function model of the current id on the acquisition loop to the voltage Vsc at the two ends of the compensating resistor is:
$${G}_{sc 2} ( s ) = \frac{{v}_{sc}}{{t}_{d}} = \frac{{Z}_{S} ( {R}_{C} + {sL}_{RC} )}{{Z}_{S} + {Z}_{C}} ;$$
wherein Z_{S}=sL_{S}+R_{S} and Z_{C}=s(L_{C}+L_{RC})+R_{C}; therefore:
$${G}_{sc 2} ( s ) = \frac{{s}^{2} {L}_{RC} {L}_{S} + s ( {R}_{C} {L}_{S} + {L}_{RC} {R}_{S} ) + {R}_{C} {R}_{S}}{s ( {L}_{S} + {L}_{C} + {L}_{RC} ) + {R}_{C} + {R}_{S}} ;$$
when L_{C}>>L_{S} and R_{C}>>R_{S}, Gsc2(s) is simplified into:
$${G}_{sc 2} ( s ) = {R}_{S} \frac{( s \frac{{L}_{S}}{{R}_{S}} + 1 ) + {s}^{2} \frac{{L}_{RC} {L}_{S}}{{R}_{C} {R}_{S}} + s \frac{{L}_{RC}}{{R}_{C}}}{( s \frac{{L}_{C} + {L}_{RC}}{{R}_{C}} + 1 )} .$$

7. The current detection circuit applied to a SiC field effect transistor according to claim 1, wherein a transfer function model of the current id on the acquisition loop to the voltage Vsc at the two ends of the compensating resistor is:
$${G}_{sc 3} ( s ) = \frac{{v}_{sc}}{{t}_{d}} = \frac{{R}_{C}}{{sR}_{C} {C}_{L} + 1} \cdot \frac{{Z}_{S}}{{Z}_{S} + {Z}_{C}} ;$$
wherein Z_{S}=sL_{S}+R_{S} and
$${Z}_{C} = {sL}_{C} + \frac{{R}_{C}}{( {sR}_{C} {C}_{L} + 1 )} ,$$
therefore:
G_{sc3}(s)=(sL_{S}+R_{S})R_{C}/(s(L_{S}+L_{C})+R_{S})(sR_{C}C_{L}+1)+R_{C},
when L_{C}>>L_{S} and R_{C}>>R_{S}, G_{sc2}(s) is simplified into:
$${G}_{sc 3} ( s ) = {R}_{S} \frac{( s \frac{{L}_{S}}{{R}_{S}} + 1 )}{( s \frac{{L}_{C}}{{R}_{C}} + \frac{{R}_{S}}{{R}_{C}} ) ( {sR}_{C} {C}_{L} + 1 ) + 1} .$$

8. The current detection circuit applied to a SiC field effect transistor according to claim 1, wherein the total parasitic inductance is obtained by double pulse measurement, and a generation model thereof is:
$${L}_{S} = \frac{{T}_{ring}^{3}}{4 {π}^{3} {C}_{oss @ Vin}} \frac{Δ {V}_{S}}{Δ {V}_{DS}} ;$$
wherein T_{ring} denotes a ringing period of a drain-source voltage of the second SiC field effect transistor, and C_{oss@Vin} denotes an output capacitance of the second SiC field effect transistor when an input voltage is Vin, wherein Δ_{DS} and ΔV_{S} denote peak-to-peak values of V_{DS} and V_{S} respectively.
